(19) United States
(12) Patent Application Publication
(10) Pub. No.: US 2024/0222172 A1
(43) Pub. Date: Jul. 4, 2024

(54) SUBSTRATE CONTAINER WITH PURGE GAS DIFFUSER

(71) Applicant: ENTEGRIS, INC., Billerica, MA (US)

(72) Inventors: Mark V. Smith, Colorado Springs, CO (US); Matthew A. Fuller, Colorado Springs, CO (US); Colton J. Harr, Monument, CO (US); Thomas H. Wilkie, Colorado Springs, CO (US); Shawn D. Eggum, Lonsdale, MN (US); Aleksandr Yakuba, Colorado Springs, CO (US)

(21) Appl. No.: 18/398,065

(22) Filed: Dec. 27, 2023

Related U.S. Application Data
(60) Provisional application No. 63/436,377, filed on Dec. 30, 2022.

(51) Int. Cl. H01L 21/673

(52) U.S. Cl. CPC H01L 21/67386

(57) ABSTRACT

Described are wafer containers adapted to store or transport semiconductor wafers in a clean environment, including containers that include a purge gas delivery device, as well as methods for purging the environment within the container.

### FIELD

The present disclosure relates to substrate containers (“wafer containers”) that are useful for storing or transporting semiconductor wafers in a clean environment, and more particularly to containers that include a diffusing gas delivery device at the interior of the container, as well as methods for purging the environment within the container.

### BACKGROUND

Semiconductor wafers and microelectronic devices that are formed at their surfaces are prepared by a series of precise processing steps, each being performed under extremely clean conditions. Between those processing steps, a wafer may be moved from one processing location to a different processing location, e.g., within a clean room or between two different clean rooms, using extremely clean conditions for the wafer during the move.

During movement of wafers between processing steps, specialized containers are used to hold and transport in-process wafers in a way that prevents damaging the wafers and that avoids introducing particle contamination or environmental contamination (e.g., moisture) to wafer surfaces. These specialized containers, sometimes referred to as “wafer containers” or “wafer carriers,” are designed to safely move semiconductor wafers in a condition that prevents physical damage to the wafers and that avoids introducing particle or environmental contamination to the wafers. Example wafer containers may be referred to as “SMIF pods” (Standard Mechanical Interface pods), “FOUPs” (Front Opening Unified Pods), or “FOSBs” (Front Opening Shipping Box). During use, these containers enclose a space to contain multiple semiconductor wafers within an atmosphere that may be evacuated (i.e., that is under reduced pressure) or may contain a gas different from air, e.g., an inert gas.

A wafer container typically includes a multi-sided container body (e.g., a “shell”) that defines a container interior, an opening to the interior on one side of the container body, a removable door that is adapted to cover the opening, and a means for producing a seal between the door and the container body, such as a gasket. One or more gas inlets and gas outlets are typically included as part of the container, to allow a desired gas to be introduced into the interior to control the gaseous atmosphere within the container.

As microelectronic devices become smaller and the number of microelectronic features per area of a wafer increases, the devices become more sensitive to particle and environmental contaminants. The effect of smaller and smaller contaminants on a microelectronic circuit increases, with contaminants of even molecular scale potentially causing a reduction in yield. Consequently, ever-improving control of particle contamination is required during all phases of manufacturing, processing, transporting, and storage of semiconductor wafers.

When a wafer container is used to transport wafers, the wafers are placed within the wafer container at a location in a clean room. The door is placed over the opening to seal the opening and enclose the interior. To control an atmosphere at the interior of the carrier, a carrier will typically include valves and gasflow devices between the interior and exterior to allow gases to be removed from or added to the carrier interior. Thus, after a container is closed and sealed with wafers at the interior, the atmosphere within the carrier interior can be, as desired, evacuated, depressurized, or replaced with a desired atmosphere such as an inert gas.

There is ever-increasing need for controlling a gaseous environment within wafer containers during handling, to achieve or maintain a high level of cleanliness.

### SUMMARY

A wafer container (a.k.a. “substrate container”) can typically include gas flow devices that are introduce a gas to a container interior, to control the atmosphere within the container interior. A gas flow device may include design and use features that control or reduce amounts of contaminants that become present at the container interior. For example, during insertion or removal of wafers to and from a wafer container, and closing and opening the door, traces of dust, gaseous impurities, or environmental contaminants such as humidity (water vapor) can be introduced into the interior of the wafer container from an exterior of the container. If these impurities contact a wafer, a potential result is reduced product yield of the resident wafers.

Wafer containers typically include gasflow openings or valves, referred to as “ports,” through which gas can flow into the container interior. As one purpose, the ports allow a gas to be dispensed into the container to fill the container interior with a desired atmosphere. A clean, inert gas (purge gas) may be dispensed into the container interior to replace a previous atmosphere. These ports may include an inlet port to inject purge gas into the container interior, and an outlet port to exhaust purge gas from the container.

For certain steps of using a wafer container, a purge gas may be dispensed into the container interior from a diffuser device that is installed at an inlet port. For a given purpose, a specific flow profile of gas from the diffuser device may be advantageous. For many functions, an evenly-distributed flow of gas along a length of a diffuser device can be useful. For other functions, a non-uniform flow of gas from a diffuser device (i.e., a non-uniform flow profile) may be desirable, for example to dispense a greater amount of gas at a particular location of a container, e.g. an upper or lower portion of the container, compared to a lower amount of gas at a different location of the container.

In some cases, it may be desirable to design a flow of gas being dispensed from a diffuser device to a specific condition or to a changing condition or event that occurs during use of the container. As an example, a diffuser may be designed to dispense gas at a particular gas flow profile during opening of the container, i.e., during removal of a door from a closed container.

In one aspect, the invention relates to a front opening wafer container. The container includes: a container interior bounded by a bottom wall, a top wall, sidewalls, and a front opening; a door to sealingly close the front opening; and a diffuser at the interior, adapted to dispense gas to the interior. The diffuser includes: an elongate body comprising: an upper end, a lower end, a front wall, a rear wall, sidewalls, a height between the upper end and the lower end, a width between the sidewalls, and a channel; a diffuser inlet that allows flow of gas into the channel; a diffuser outlet that comprises one or more openings in the front wall, a sidewall, or both; and flow control structure within the channel that directs flow of gas along a length of the channel between the diffuser inlet and the diffuser outlet.

In another aspect, the invention relates to a diffuser that includes: an elongate body comprising an upper end, a lower end, a front wall, a rear wall, sidewalls, a height between the upper end and the lower end, a width between the sidewalls, and a channel; a diffuser inlet that allows flow of gas into the channel; a diffuser outlet that comprises one or more openings in the front wall or a sidewall or both; non-porous channel surfaces comprising a non-porous rear wall surface and non-porous sidewall surfaces; and flow control structure within the channel that directs flow of gas along a length of the channel between the diffuser inlet and the diffuser outlet.

### BRIEF DESCRIPTION OF THE DRAWINGS

FIGS. 1A through IF show different views of various example diffuser devices as described.

FIGS. 2A through 2D show example top views of rear plates of example diffuser devices, side views of the example diffuser devices, and flow profiles of the example diffuser devices.

FIGS. 3A and 3B show an example substrate container as described.

All figures are schematic and not to scale.

### DETAILED DESCRIPTION

The following describes wafer containers that include a container body that has an interior and an opening to access the interior, a door to cover the opening, and one or more diffusers at the interior to dispense gas into the interior. The diffuser is a type of diffuser referred to as a “directional” gas diffuser, which is a type of diffuser that is used to dispense a gas (e.g., a “purge gas”) into an interior of a wafer container with directional specificity relative to the diffuser. The diffuser includes a housing, a diffuser inlet, a diffuser outlet, an open internal “channel” within the housing that connects the diffuser inlet to the diffuser outlet and allows fluid communication from the inlet, through the channel, to the outlet. The diffuser additionally includes one or more flow control structures within the channel such as a baffle, diverter, cowling, or the like, that affect the flow of a gas through the channel and through the diffuser between the inlet and the outlet, to provide a desired flow profile of the gas through the outlet.

The present disclosure also relates to specific diffuser assemblies, to wafer containers that include the diffuser assembly, and to methods of using a diffuser as part of a wafer container that includes the diffuser.

A wafer container includes a multi-sided container body (sometimes referred to as a “shell”) that defines a container interior that is adapted to contain and support one or more semiconductor wafers. The body includes an opening (“container opening”) that allows access to the container interior on one side of the container body. The container also includes a door that is adapted to cover the opening and form a seal over the opening between the interior and the exterior of the container.

A wafer container can typically include at least one inlet port to inject a gas, e.g., a “purge gas,” into the container interior, as well as at least one outlet port to exhaust gas from the container.

According to the present description, a wafer container includes an inlet that includes a diffuser device, or multiple inlets that each include a diffuser device. A diffuser device, or “diffuser,” has a diffuser inlet that receives a gas flowing to the diffuser, a diffuser outlet, and a channel that extends within the housing between the diffuser inlet and the diffuser outlet to allow a gaseous fluid to flow into the diffuser, then through the channel, and then through the diffuser outlet. A flow of gas enters the diffuser inlet, flows through the channel with guidance from flow control structure within the channel, and then flows through the diffuser outlet in a manner that diffuses (disperses) the gas as the gas is dispensed from the diffuser outlet and into the wafer container.

For particular wafer container designs or for particular steps of using a wafer container, a diffuser may be designed to dispense a gas into the container with a specific flow profile of the gas dispensed from the diffuser outlet. In certain circumstances, a diffuser may be adapted to dispense a flow of gas into a wafer container with a high degree of uniformity of the gas dispensed along a length of the diffuser and diffuser outlet. In other variations, a gas that is dispensed from a diffuser may be desirably delivered with a flow profile from the diffuser outlet that varies along a length of the diffuser outlet. For example a diffuser may be designed to deliver a greater flow of the gas through one portion of the diffuser outlet, e.g., an end portion, and a relatively lower flow of the gas through a different portion of the diffuser outlet, e.g., a middle portion. The diffuser may deliver a greater flow of gas to an upper portion of the container and a relatively lower flow of gas to a lower portion of the container, or vice versa, a lower flow of gas to an upper portion of the container and a relatively greater flow of gas to an upper portion of the container.

In particular examples, a diffuser may dispense a flow of gas from a diffuser outlet with a flow profile that is designed to provide a desired effect during a step of using the wafer container, such as in response to a changing condition or flow event that occurs in the container during usc.

One event that causes changing conditions within a container is a step of closing or opening a door to the container. When a door of a wafer container is removed during use, gas at the interior of the container (container “interior gas”) and gas outside of the container (container “exterior gas”) are caused to flow between the container interior and the container exterior, with an exchange of the interior gas and the exterior gas occurring at the door opening. The exterior gas may contain a higher level of contaminants compared to the interior gas. Contaminants may include particles, a chemical vapor (e.g., molecules of organic compounds, sometimes referred to as “volatile organic compounds”), as well as environmental vapors such as water vapor (humidity).

As a door is removed from a container opening, an exchange of gases naturally occurs at the opening with interior gas flowing out from the container through the opening while exterior gas flows from the exterior into the interior. An example of a useful flow profile of gas dispensed from a diffuser may be a flow profile that reduces the amount of exterior gas that flows from the exterior into the container interior during a step of removing a door from a wafer container. The flow may exhibit any useful profile along the height or the width of the diffuser. The flow may be uniform along the height with substantially equal flow of gas dispensed at the upper end, lower end, and middle portion of the diffuser. Alternately, a flow profile along the height of the diffuser may be non-uniform, with a higher flow rate of gas from the upper end of the diffuser and a lower flow rate of gas from the lower end of the diffuser, or with a lower flow rate of gas from the upper end of the diffuser and a higher flow rate of gas from the lower end of the diffuser.

A specific flow profile from a diffuser may be selected based on a condition and process being performed within the substrate container, such as whether the door is opened or closed or a type of gas being introduced through the diffuser. Gas may be introduced through the diffuser at a useful profile for a purpose of filling the container interior with a gaseous atmosphere. Alternately, gas may be introduced through the diffuser at a flow profile useful to purge an atmosphere from the interior, which may occur either with the door opened or with the door closed.

A diffuser as described includes a diffuser housing (also referred to herein as a “diffuser body”) that includes a first end (e.g., an upper end), a second end (e.g., a lower end), a front wall (which may include a diffuser outlet), a rear wall, sidewalls, and a diffuser inlet. The body defines a length (which is a height when the body is oriented vertically, e.g., when installed in a container) between the first end and the second end, and a width between the sidewalls. At the housing interior is an interior space that may be referred to as a “channel” that connects the diffuser inlet and the diffuser outlet (a.k.a., an open interior “passageway” or “opening”) that is defined by interior surfaces of the front wall, rear wall, sidewalls, ends, and by flow control structure, and that causes and allows fluid communication between the diffuser inlet and the diffuser outlet.

Examples of channels can be made up of different interior spaces (“chambers”) and structures relative to interior surfaces of the front wall, sidewalls, rear wall of the body, and flow control devices. Specific spaces and structures include an inlet, an inlet chamber, a flow control device, a plenum chamber, and an outlet.

The inlet (referred to as a “diffuser inlet” or a “channel inlet”) allows gas to enter into the channel from a location exterior to the diffuser body. In some example diffuser devices, connected to the inlet is an internal space referred to as an inlet chamber, which is between the inlet and a flow control device. The flow control device separates the channel into portions that include an inlet chamber and an outlet chamber (a.k.a. “plenum chamber”). The plenum chamber is on an opposite side of a flow control device from the inlet chamber, and is connected to an outlet (“diffuser outlet” or “channel outlet”) that allows the gas to pass from the channel into an interior of a substrate container that includes the diffuser.

The inlet may be located at any position along a length of the diffuser, such as at an end or at a location along the length between the first end and the second end. According to certain examples, an inlet may be located at an end of the diffuser or at a middle third of the length of the diffuser, e.g., approximately half-way between the first end and the second end.

The diffuser outlet includes one or multiple openings in a wall (front wall or side wall) or end structure of the housing, such as in the front wall or a sidewall of the housing, in any useful form. In one example an outlet may include multiple individual openings that are distributed evenly along a length of the front wall. Alternately, a diffuser outlet may include a length-wise slot extending (e.g., uniformly) along some or all of the length of the front wall or a sidewall. In these examples, an outlet may be a set of uniform (in size and spacing) openings, or a single uniform opening that is substantially evenly distributed along a length of the diffuser, through a sidewall or a front wall.

In other examples, a diffuser outlet may include one or more openings that are distributed non-uniformly along a length of a diffuser body, on a front wall or a sidewall, e.g., with more or fewer, or larger or smaller openings located at one portion of a front wall or sidewall compared a different portion of the front wall or sidewall, based on position along the length between the first end and the second end. For example, to cause a diffuser outlet to dispense gas at a higher volume from one or two ends of the diffuser, and to dispense less gas at a middle portion of the length of diffuser, the diffuser outlet may include more openings or larger openings near the first end or near the second end, and fewer or smaller openings near the middle portion of the length of the front wall or sidewall. In certain example diffusers, a middle portion of a length of a diffuser body may not include any openings; e.g., a middle ⅕, middle ¼, or a middle ⅓ of a length of a diffuser body may contain no openings and no portion of a diffuser outlet, and the diffuser outlet may be located only at the remaining end portion lengths of the diffuser body.

Additionally or alternately, a diffuser outlet may include openings in the front wall that are distributed either uniformly or non-uniformly along a width of a front wall. When positioned vertically within a wafer container, a diffuser may be considered to include a forward portion of the width (toward a front opening of a container) a rearward portion of the width (toward a rear of the container interior) and a middle portion of the width (between the forward portion and the rearward portion). The forward portion may be the front ½ of the width, or the front ⅓ of the width, or the front ¼ of the width. The rearward portion may be the rear ½ of the width, or the rear ⅓ of the width, or the rear ¼ of the width. A front wall may optionally contain openings exclusively at one of these portions, e.g., at only a front ½, a front ⅓, or a front ¼ of the width of the front wall.

Also optionally, a diffuser outlet may include openings that direct a flow in a direction that is non-perpendicular relative to a surface of the diffuser body. The openings may pass through the front wall or sidewall at a non-perpendicular angle to direct flow through the front wall or sidewall in a direction toward a front of a container or toward a rear of a container, with the diffuser oriented vertically within the container.

To produce a desired flow profile from a diffuser, the diffuser body may include a diffuser outlet in the form of one or multiple openings of various sizes, with the openings being located at exclusively a forward portion, exclusively a rearward portion, or exclusively a middle portion between the forward portion and the rearward portion. As an example, in a diffuser located at a front portion of a container, near a container opening, the front wall of the diffuser may include diffuser outlet openings only at a forward portion of the diffuser width. The diffuser outlet openings may be directed toward the container opening or through the container opening, with the flow of the gas from the diffuser being designed to reduce the exchange of exterior gas and interior gas through the container opening during a step of removing a door of the container.

A diffuser of this description is a type of diffuser referred to as a “directional” diffuser, which is a type of diffuser that is used to dispense a gas (e.g., a “purge gas”) in a direction-specific manner. A directional diffuser includes features that are different from other general types of diffusers such as “showerhead” diffusers, “tube” diffusers, “disk” diffusers, and “plate” diffusers. A directional diffuser has a form that includes an elongate diffuser body with a length between two ends, and a diffuser outlet that extends along the length of the body between a first end and a second end, on one side of the diffuser body and not on all sides of the diffuser body.

The diffuser outlet may optionally include a diffuser membrane, which is a porous solid body that allows flow of a gaseous fluid through the porous body, while being semi-resistant to the flow of the gas, allowing gas under moderate pressure to flow through the membrane as a dispersed or “diffused” stream directed from only one side of the diffuser housing. The gas flows into the diffuser housing at the inlet, flows through the channel along the length of the housing, is controlled, affected, or diverted by a flow control structure within the channel, and then exits the housing through the diffuser outlet and optional porous diffuser membrane from one or more sides of the diffuser body but not all sides that surround the circumference of the diffuser body. On the remaining portions of the housing (the sides that don't include the diffuser outlet) are non-porous surfaces that enclose the interior channel between the first end and the second end along the length of the housing.

The diffuser is described as “directional” because the gas is dispensed directionally relative to an outer circumference of the diffuser, when the diffuser is viewed in a direction of the diffuser length. The flow of gas from the diffuser outlet does not occur in all directions of the circumference (i.e., at all 360 degrees of the circumference). Instead, the diffuser outlet is positioned at only a portion of the circumference, sometimes referred to as an outlet side of the housing. The portion of the housing through which the lateral flow occurs may be less than half of the entire circumference, e.g., flow may occur over up to 180 degrees of the circumference, e.g., over a range from 10 to 170 degrees, or from 20 to 150 degrees, or from 40 to 120 degrees.

A benefit of directional flow from the diffuser over less than the entire circumference is an ability to control direction and placement of gas flow into a chamber interior. The flow may be directed for a purpose of avoiding a direct flow of gas into an area of a chamber interior at which particle contamination may exist. Direct flow of gas toward particles that have become settled at areas of a chamber interior can disrupt and disperse the particles within the chamber, which is preferably avoided.

The directional diffuser has a length dimension between the first end and the second end, a width that is transverse to the length, and a depth that is transverse to the length and width. The directional diffuser is elongate, having a length that is greater than the width and that is greater than the depth. Example directional diffusers may have a length that is at least 2, 4, 5, 10, 12, 15, 20, or 30 time the magnitude of the depth, or the width, or both, measured at exterior surfaces of the housing.

According to the present description, the diffuser includes a channel within the housing and a wall of the channel that includes flow control structure, which may be the rear wall, the front wall, or both. A wall of the channel includes a “base surface” that covers most of the wall surface. The rear wall includes a rear wall base surface and may include one or more flow control structures that extend from the base surface a distance above the base surface and into the channel. The base surface of the rear wall extends semi-continuously along the width of the diffuser and between the first end and the second end, optionally interrupted by a flow control structure and other structures such as an inlet opening in a rear wall. The base surface may be flat (substantially planar) or slightly curved along the width dimension or along the length dimension.

Alternately or in addition to flow control structure at an interior surface of a rear wall, a diffuser may include a flow control structure that is part of an interior surface of a front wall. The front wall also include a “base surface” that covers most of the front wall interior surface, and may include one or more flow control structures that extend from the front wall base surface a distance above the base surface toward the channel. The base surface of the front wall extends semi-continuously along the width of the diffuser and between the first end and the second end, interrupted by any optional flow control structures and by other structures such as one or more outlet openings in the front wall. The base surface may be flat (substantially planar) or slightly curved along the width dimension or along the length dimension.

A flow control structure can be any structure that extends from a base surface of a front wall or a rear wall in a direction toward the channel, into the channel, and that is effective to contact and disrupt or divert a flow of gas directed through the channel along the base surface. The flow control structure can be any shape or form of a structure that directs a flow of gas along the base surface. Examples of flow control structures include: a baffle, a diverter, a wall, a cowling, or the like. The flow control structure affects a flow of the gas at the base surface, which affects the flow of the gas within the channel, which can affect the level (volume, rate, or both) of flow through different parts of the channel and the diffuser outlet to provide a desired flow profile of the gas through the diffuser outlet.

The flow control structure can produce a desired flow profile of gas through the diffuser outlet. A desired effect of a flow control structure may be to produce a flow profile through the diffuser outlet that is uniform along the length of the outlet. Alternately, a desired effect of a flow control structure may be to produce a flow profile through the diffuser outlet that is non-uniform along the length or width of the outlet, such as a flow that is higher at one end of the diffuser outlet and lower at a second end of the diffuser outlet, or higher at one portion of the width (e.g., a forward portion) of the diffuser and lower at a different portion of the width (e.g., a rearward portion).

A flow control structure can be any form, shape, height or length, and may be stationary or moveable (relative to a base surface, the channel, or both) based on a spring (biased by a spring), or may be moveable mechanically and remotely by a remote control device.

As an example, a type of flow control structure is a stationary, vertical (relative to the base surface held horizontally) “wall” structure that extends into the channel from the base surface. The wall-type flow control surface can have a linear or curved form along a length of the wall and the base surface, a height in the direction of the channel, and width dimension along the base surface transverse to the length. Example wall structures can have a substantially rectangular cross-section when viewed along the length of the structure. The width may be minimal, e.g., less than 5, 3, or 2 millimeter.

A height of a wall-type flow control structure may be as desired to cause a diverted flow of gas along the base surface. A height of a flow control structure (wall-type or otherwise) may be sufficient to extend from the base surface to the interior surface of the front wall to leave minimal space between the flow control surface and the front wall, to maximize the flow-diverting effect of the flow control surface. The channel can be considered to have a depth that is a distance from the rear wall base surface to an interior surface or base of the front wall. A height of a flow control structure may be at least 75 percent, 80 percent, or 90 percent of a depth of the channel.

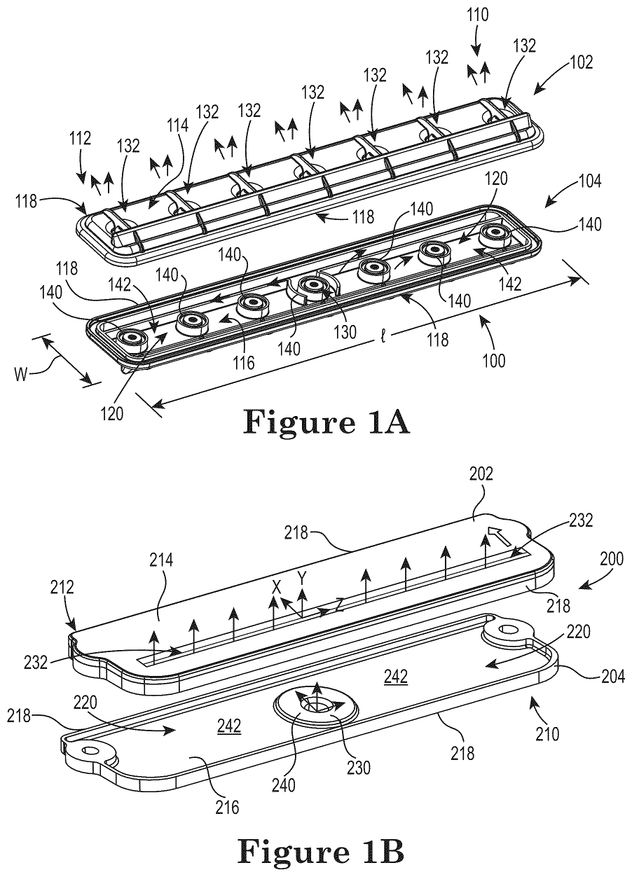

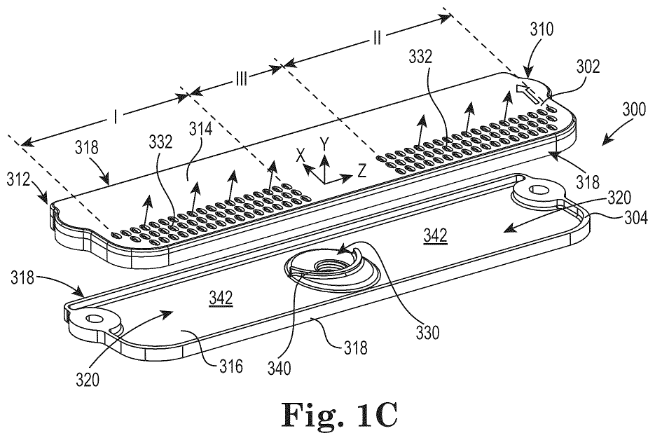

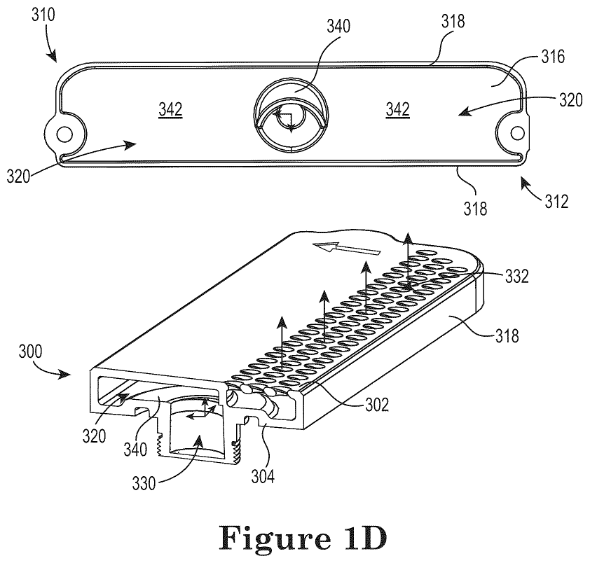

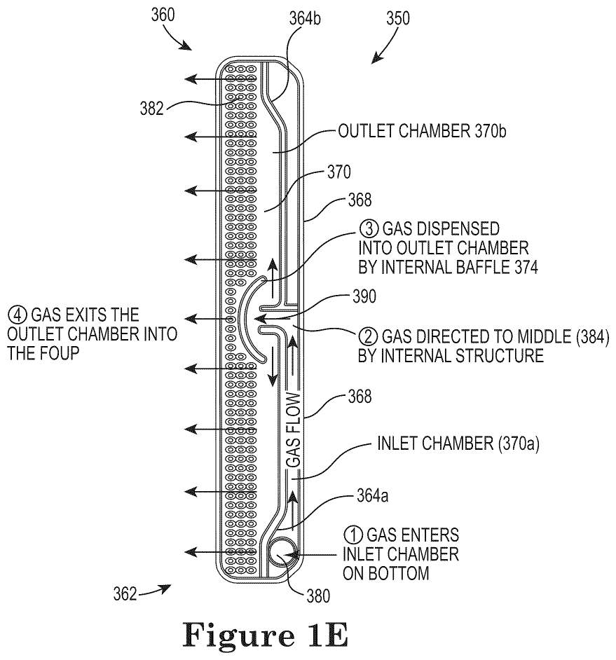

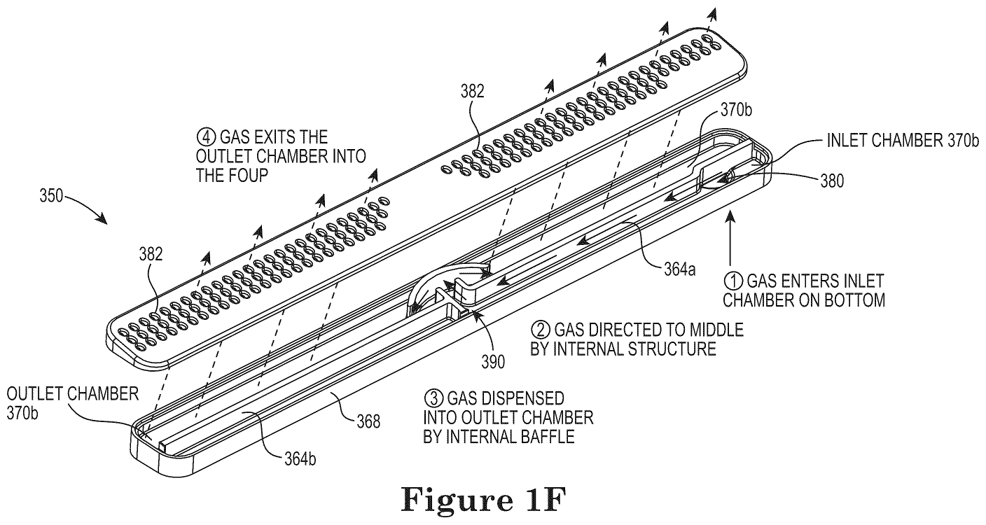

Referring to FIG. 1A, illustrated is an example of a diffuser as described. Diffuser 100 includes a front plate 102 and a rear plate 104. The front plate and the rear plate can be assembled by placing the front plate in contact with the rear plate to form a diffuser housing that defines a channel between the front plate and the rear plate. Each of the front plate 102, the rear plate 104, and the housing formed from the assembled plates, includes a first end (e.g., an upper end) 110, a second end 112, a front wall 114, a rear wall 116, and sidewalls 118. The housing defines a length (“1”) between first end 110 and second end 112, and a width (“w”) between sidewalls 118. With front plate 102 and rear plate 104 assembled and contacting one another at the sidewalls and ends, the opposed plates form a channel 120 at the interior, defined by interior surfaces of the front plate, rear plate, sidewalls, and ends.

Diffuser 100 includes an inlet (referred to as a “diffuser inlet” or a “channel inlet”) 130 that allows gas to enter into channel 120 from a location exterior to the diffuser body, as well as an outlet (“diffuser outlet” or “channel outlet”), which includes multiple outlet openings 132 as illustrated, with each outlet opening allowing gas to pass from channel 120 to an exterior of diffuser 100 (see arrows), for example into a wafer container interior that contains diffuser 100. Inlet 130 as illustrated is located at a position approximately mid-way between ends 112 and 110. Outlet openings 132 are positioned intermittently and spaced regularly along the length of diffuser 100 between first end 110 and second end 112.

Rear wall 116 includes base surface 142, which is a substantially flat, planar surface between sidewalls 118 and ends of rear wall 116. Base surface 142 is interrupted by inlet 130 and also by flow control structures 140. Flow control structures 140 are in the form of curved, circular walls or rings that extend from base surface 142 to a height into channel 120. Gas that enters inlet 130 enters channel 120 and flows from the location of inlet 130 toward ends 110 and 112. As the gas flows within channel 120 toward ends 110 and 112, the direction of the gas is diverted by flow control structures 140. The gas passes from channel 120 through outlet openings and into an interior of a wafer container. Optionally, not illustrated, the inner surface of front wall 114 can also include flow control surfaces that extend into channel 120 to control or divert a flow of fluid through channel 120.

Referring next to FIG. 1B, illustrated is another example of a diffuser as described. Diffuser 200 includes a front plate 202 and a rear plate 204. The front plate and the rear plate can be assembled by placing the front plate in contact with the rear plate to form a diffuser housing that defines a channel 220 between the front plate and the rear plate. Each of the front plate 202, the rear plate 204, and the housing formed from the assembled plates, includes a first end (e.g., an upper end) 210, a second end 212, a front wall 214, a rear wall 216, and sidewalls 218. The housing defines a length between first end 210 and second end 212, and a width between sidewalls 218. With front plate 202 and rear plate 204 assembled and contacting one another at the sidewalls and ends, the opposed plates form channel 220 at the interior, defined by interior surfaces of the front plate, rear plate, sidewalls, and ends.

Diffuser 200 includes an inlet 230 that allows gas to enter into the channel from a location exterior to the diffuser body, as well as a diffuser outlet 232. As illustrated, outlet 232 forms a length-wise opening or slot that extends between end 210 and end 212, that allows gas to pass from channel 220 to an exterior of diffuser 200 (see arrows).

Rear wall 216 includes base surface 242, which is a substantially flat, planar surface between sidewalls and ends of rear wall 216. Base surface 242 is interrupted by inlet 230 and also by flow control structure 240. Flow control structure 240 is an annular ring that surrounds inlet 230. Gas that enters inlet 230 enters channel 220 and flows from the location of inlet 230 toward ends 210 and 212. As the gas flows within channel 220 toward ends 210 and 212, the gas can pass through outlet 232 along the length of outlet 232.

Referring to FIG. 1C, illustrated is another example of a diffuser as described. Diffuser 300 includes front plate 302 and rear plate 304, which can be assembled by placing the front plate in contact with the rear plate to form a diffuser housing that defines channel 320 between the front plate and the rear plate. Each of the front plate 302, the rear plate 304, and the housing formed from the assembled plates, includes a first end (e.g., an upper end) 310, a second end 312, a front wall 314, a rear wall 316, and sidewalls 318. The housing defines a length between first end 310 and second end 312, and a width between sidewalls 318. With front plate 302 and rear plate 304 assembled and contacting one another at the sidewalls and ends, the opposed plates form a channel 320 at the interior, defined by interior surfaces of the front plate, rear plate, sidewalls, and ends.

Diffuser 300 includes inlet 330 that allows gas to enter into channel 320 from a location exterior to diffuser 300. Diffuser 300 includes diffuser outlet 332, as part of front plate 302. As illustrated, outlet 332 includes a series of circular openings that extend along a length-wise portion of 302 between end 310 and end 312. The openings allow gas to pass from channel 320 to an exterior of diffuser 300 (see arrows).

Rear wall 316 includes base surface 342, which is a substantially flat, planar surface between sidewalls and ends of rear wall 316. Base surface 342 is interrupted by inlet 330 and also by flow control structure 340, adjacent to inlet 330. Flow control structure 340 includes an annular ring that surrounds inlet 330, and a semi-circular cowling disposed on one side of inlet 330, between inlet 330 and sidewall 318. Gas that passes through inlet 330 and enters channel 320 flows from the location of inlet 330 toward ends 310 and 312. As the gas flows within channel 320 toward ends 210 and 212, the gas can pass through individual openings that make up outlet 332 along the length of outlet 332. The openings of outlet 332 are positioned at two regions along the length of front plate 314: region I between end 310 and a middle portion of front plate 314 along the length; and region II between end 312 and a middle portion of front plate 314. Front plate 314 does not include openings at region III, at a middle portion of front plate 314, including at a portion of plate 314 that is opposite to inlet 330.

FIG. 1D shows a top view of rear plate 304 and a side-perspective cut-away view of an assembled diffuser 300 made by engaging rear plate 304 and front plate 302 at sidewalls 318 to form an interior that includes channel 320. Gas flows into diffuser inlet 330, into channel 320, and along channel 320 toward ends 310 and 312, and through individual openings of diffuser outlet 332.

FIGS. 1E and 1F show another example of a diffuser that includes a channel with flow control structures to direct flow of fluid through the channel from an inlet to an outlet and through an inlet chamber and an outlet chamber. Referring to FIG. 1E, diffuser 350 includes a front plate and rear plate (not specifically shown at FIG. 1E), can be assembled to form a diffuser housing that defines channel 370, which includes inlet chamber 370a and outlet chamber (or “plenum chamber”) 370b. Diffuser 350 includes the housing formed from the assembled plates, a first end (e.g., an upper end) 360, a second end 362, front wall, a rear wall, and sidewalls. The housing defines a length between first end 360 and second end 362, and a width between the sidewalls.

Diffuser 350 includes inlet 380 at end 362, that connects to inlet chamber 370a of channel 370, and allows gas to enter channel 370, at inlet chamber 370a, from a location exterior to diffuser 350. Also connected to channel 370, specifically to outlet chamber 370b, is diffuser outlet 382. As illustrated, outlet 382 includes a series of circular openings that extend along a length of diffuser 350 between ends 360 and 362. The outlet 382 allows gas to pass from outlet chamber 370b of channel 370, to an exterior of diffuser 350 (see arrows).

In more detail, diffuser 350 includes flow control structures that direct flow of gas from inlet 380, into and through inlet chamber 370a of channel 370 that extends in the length direction from inlet 380 to middle portion (based on length) 384 of diffuser 350. Inlet chamber 370a is defined in part by wall (e.g., sidewall) 368, and by flow control structure 364a, i.e., wall 364a.

Wall 364a extends length-wise within channel 370 from end 362 to middle portion 384. A second wall section, 364b, extends length-wise within channel 370 from end 360 to middle portion 384. Both wall sections 364a and 364b extend to middle portion 384 but the two wall sections do not connect, and instead form flow gap 390 as part of channel 370 that connects inner chamber 370a to outer chamber 370b.

In use, gas flows through inlet 380 to enter inlet chamber 370a at a location of end 362 of diffuser 350. The gas flows through inlet chamber 370a to middle portion 384 of diffuser 350. The gas flows from inlet chamber 370a, through gap 390, into outer chamber 370b, and eventually flows through outlet 382.

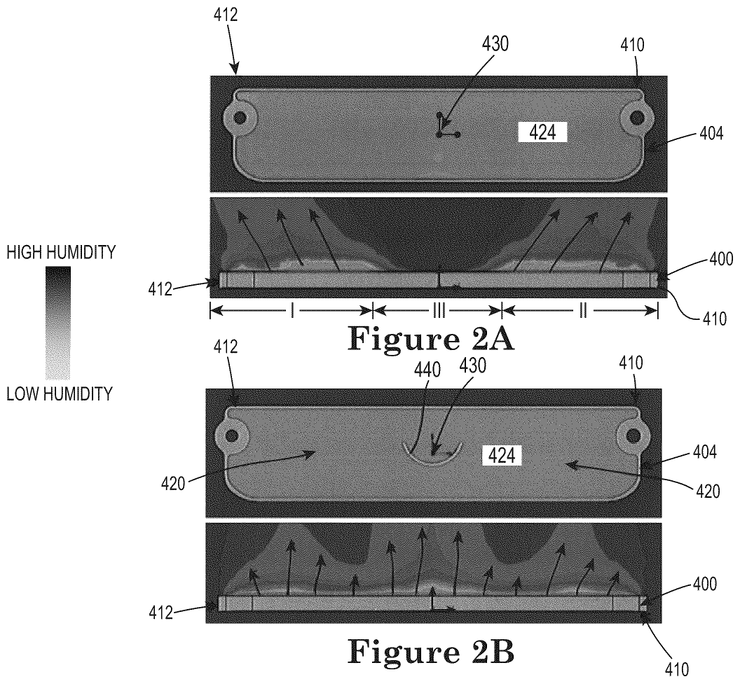

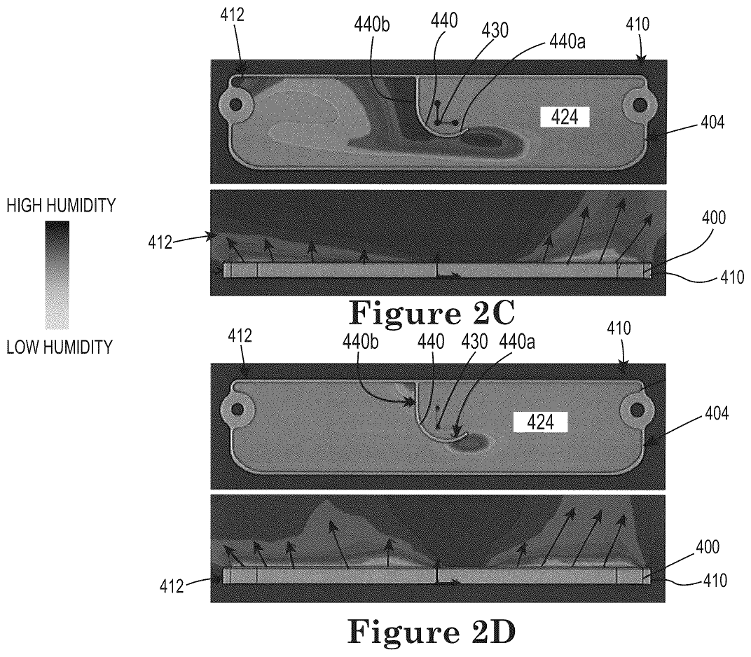

Referring now to FIGS. 2A through 2D, these figures show examples of diffusers 400 that include bottom plate 404, and a front plate (a.k.a. top plate, not illustrated). A top window of each figure shows a top view of bottom plate 404 A lower window of each figure shows a side view of diffuser 400, and an indication above diffuser 400 of a flow profile of gas flowing through a diffuser outlet of a top plate of diffuser 400 based on a detected level of humidity within the flow as measured by computational fluid dynamic (“CFD”) techniques.

Each diffuser 400 includes structures found in a diffuser as described, including ends 410 and 412, a front plate and rear plate that form an assembled diffuser housing, a diffuser inlet, and a diffuser outlet. The housing defines a length between first end 410 and second end 412, a width between sidewalls, and a channel within the assembled housing. The rear plate has a base surface 424, an inlet 430 at a central region (approximately half-way between the ends and half-way between the sidewalls), and a flow control structure 440 at the central region.

FIG. 2A shows diffuser bottom plate 404, which includes base surface 424 having inlet 430. Bottom plate 404 is assembled with a top plate (not shown) that has a slot-type opening extending uniformly and continuously along portions I, II, and III of the top plate, for example as with top plate 218 shown at FIG. 1B. Base surface 424 does not include a flow control structure, and is considered a “control” example, for comparison to other base surfaces that do include a flow control structure according to the present description.

When gas is flowed through diffuser 400 of FIG. 2A (through inlet 430, through the interior channel of diffuser 400, and then through diffuser outlets), the gas flows through the slot-type diffuser outlet in a profile shown by the bottom window of FIG. 2A. Gas enters the channel by passing through an inlet 430 at a center portion of base surface 424, and builds backpressure within the interior channel between the top plate and the bottom plate, then exits the slot-type outlet extending uniformly along the front wall at portions I, II, and III.

The flow profile at FIG. 2A (bottom) shows non-uniform flow of gas from the diffuser outlet based on position along the length of the diffuser. From the middle third (portion III) of the length of diffuser 400, a low flow or no flow of gas occurs. At end portions I and II (e.g., the approximate ⅓ of the length of the diffuser at each end), a higher level of flow occurs, with substantially all of the flow from diffuser 400 occurring at the end portions I and II of the total length of the diffuser, with little flow from middle portion III of the length.

FIG. 2B shows a different example of diffuser bottom plate 404, which includes base surface 424 having inlet 430 and flow control structure 440. A top plate (not shown) that is assembled with bottom plate 404 to form an assembled diffuser device has an outlet in the form of a narrow slot that extends along the length of the top plate between the two ends, for example as shown with top plate 218 of FIG. 1B. Flow control structure 440 is a semi-circular stationary wall that partially surrounds inlet 430, and extends from base surface 424 into channel 420, toward the front wall and optionally contacting or nearly contacting the front wall. Flow control surface 440 diverts a flow of gas from inlet 430 in a direction of one side of channel 420, and inhibits or prevents flow of gas directly from inlet 430 to the opposite side of channel 420.

The flow profile of gas flowing through diffuser 400 of FIG. 2B is shown at the lower window of FIG. 2B. When gas flows through diffuser 400 (through inlet 430, through channel 420 of diffuser 400, and then through the diffuser outlet), the gas is diverted by flow control structure 440 and directed equally toward the end portions of diffuser 400. The flow profile shows flow of gas from the slot-type diffuser outlet (not shown) based on positions along the length of the diffuser. Each of the middle portion III and end portions I and II of the length of diffuser have slightly different gas flow through a diffuser outlet. The flow varies somewhat along the length as shown by the length of arrows, but the flow can be considered to be substantially uniform along the length of the diffuser device.

FIG. 2C shows another example of diffuser bottom plate 404, which includes base surface 424 having inlet 430, and flow control structure 440. A top plate (not shown) that is assembled with bottom plate 404 to form an assembled diffuser device has an outlet in the form of a narrow slot that extends along the length of the top plate between the two ends, for example as shown with top plate 218 FIG. 1B.

Flow control structure 440 includes a stationary semi-circular wall portion 440a that partially surrounds inlet 430, and straight portion 440b that is connected to semi-circular wall portion 440 and extends to and connects to a sidewall of diffuser 400. Wall portion 440 extends toward the front wall and optionally contacts or nearly contacts the front wall. Flow control structure 440 diverts a flow of gas from inlet 430 in a direction of one side of channel 420, and in a direction toward one end of channel 420, and inhibits a flow of gas directly from inlet 430 to the opposite side of channel 420 or to the opposite end of channel 420.

Flow control structure 440 is attached to a sidewall of 404 and causes the flow of gas within the channel to move toward the two ends, in different amounts, to produce an outlet flow profile that is significantly non-uniform between the two ends and the middle portion of the outlet. A non-uniform outlet flow profile may be useful to direct a specific type of gas to a specific locations within a substrate container, toward a different location of substrates (wafers) contained in a substrate holder, for example depending on whether the gas is more dense or less dense than an atmosphere that is being replaced (a purge gas may be lighter or heavier than an air atmosphere within a substrate container). The feature 440 may be movable or adjustable to redirect the gas in real time.

The flow profile of gas flowing through diffuser 400 of FIG. 2C is shown at the lower window of FIG. 2C. When gas flows through diffuser 400 (through inlet 430, through the interior channel of diffuser 400, and then through diffuser outlets), the gas is diverted by flow control structure 440 and directed toward one end portion (II) of diffuser 400, and is prevented from flowing directly to the opposite end portion (I). The flow profile shows non-uniform flow of gas from the diffuser outlet based on position along the length of the diffuser. Gas flows at a highest amount through length portion II toward one end (end 410) of diffuser 400. A lower amount of flow occurs at length portion I at the opposite end of diffuser 400. The lowest amount of flow occurs at middle portion III on the side of end II.

FIG. 2D shows diffuser 400 having a structure that is comparable to that of diffuser 400 of FIG. 2C. A difference between diffuser 400 of FIG. 2C and diffuser 400 of FIG. 2D is the width of the slot that forms the outlet of the top plate (not shown). The width of the outlet slot can affect the velocity of the purge gas through the outlet. A narrower outlet slot tends to act like a nozzle, which diffuses the gas at higher velocity than a wider outlet slot. With the different widths of slot openings of diffuser outlets of diffusers of FIGS. 2C and 2D, the pressure of the gas as the gas flows through the respective diffuser channels is different, which produces a different flow profile as shown at the bottom window of each of FIGS. 2C and 2D.

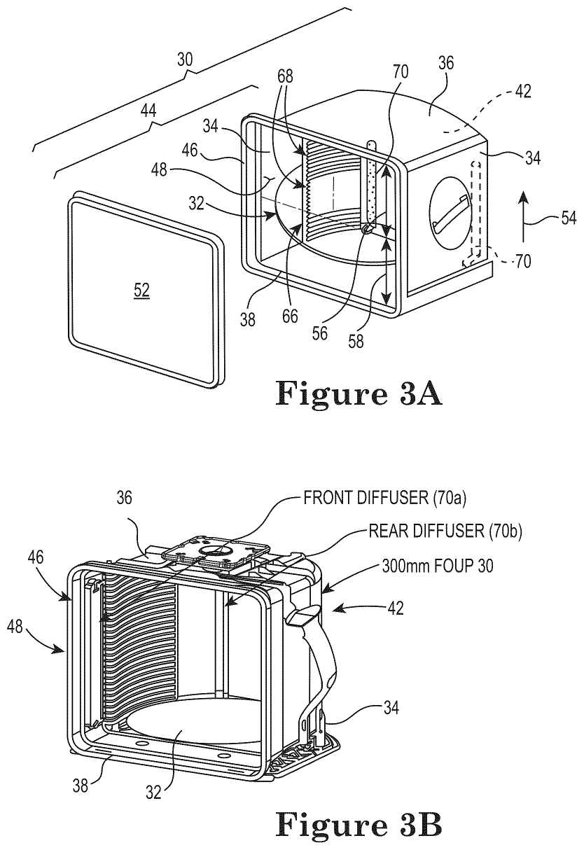

Referring to FIGS. 3A and 3B, illustrated are example wafer containers 30, adapted to hold and transport one or more substrates 32. Substrate container 30 includes two opposing side portions 34, a top portion 36, a bottom portion 38, and a back portion (back wall) 42. Front portion 44 includes a door frame 46 that defines an opening 48. Door 52 is adapted to scalably cover opening 48. Opening 48 lies on a plane that is substantially parallel to a vertical direction 54. Substrate 32 may be any of a variety of different generally flat structures that are typically carried in a container such as container 30 for safe and clean handling, to avoid damage or contamination. Example structures include structures semiconductor waver structures, precursors thereof, derivatives thereof, and in-process versions of any of these, including semiconductor wafers, in-process microelectronic devices, EUV (extreme ultraviolet light) reticle pods, panels, or other structures known to be carried or contained in a carrier as described herein, any of which may be referred to generically as a “wafer” or a “substrate.”

A pair of slotted sidewalls 66 are disposed within substrate container 30, each being proximate a respective one of the side portions 34. Slotted sidewalls 66 are aligned for slots to face each other to define a plurality of slot positions 68, and are spaced apart to allow multiple substrates 32 to be supported therebetween.

Substrate container 30 further includes at least one diffuser assembly 70 disposed within substrate container 30 and operatively coupled to a gas source (not depicted) for dispensing a gas into substrate container 30.

At FIG. 3B, an example wafer container 30 is shown to be adapted to contain wafers 32 having a 300 millimeter diameter, and includes two diffuser assemblies, 70a and 70b. Diffuser 70a is located at a front third of container 30, near opening 48. Diffuser 70b is located at a rear third of container 30, near back portion 42.

The diffuser can be used in a wafer container as described for holding and transporting one or more semiconductor wafers or any other substrate at an interior of the container. The container interior (sometimes referred to as a “microenvironment”) can be evacuated, or may be filled with a desired gaseous atmosphere, e.g., an inert gas such as nitrogen, clean dry air, or another desired gas.

In use, one or more wafers are placed at the container interior. The wafers and container will normally be in a clean room that has a controlled atmosphere and very low levels of particle and environmental contaminants. The door of the wafer container is placed over the opening of the wafer container with a sealed closure between the door and the container opening that inhibits flow of gas between a container interior and a container exterior. The container can be moved, for example between locations in a clean room, or from one clean room to a different clean room. In example containers, the container includes a diffuser as described herein, which is located at a front portion of the container, e.g., at a front half or at a front third of the interior. (measured from the opening frame toward the a back wall).

After the door is closed, the gaseous environment at the enclosed interior may be left as is, i.e., an environment of the clean room location where the wafers were loaded into the container and the container was closed. Alternately, the interior gaseous atmosphere may be removed from the interior (i.e., displaced by a different gas) and the container interior may be held at a reduced pressure, at a partial vacuum. Optionally, the interior may be filled with a gas that is different from the original interior gas by dispensing a gas (e.g., a “purge gas”) from a diffuser of the present description into the interior. The purge gas may be an inert gas (e.g., at least 99 percent concentrated nitrogen, helium, or the like) or clean dry air (air having a relative humidity below 5 percent or below 1 percent).

After moving the container to a destination, the substrates within the container (e.g., semiconductor wafers) can be removed from the container by first removing the door from the container. During or prior to a step of removing the door from the container, a purge gas may be dispensed into the container interior, through a diffuser as described. The gas may be dispensed as the door is being removed, and for a period of time after the door is away from the container opening. In an open-door purge method, the door is opened and the purge gas is caused to flow into the substrate container interior to replace the atmosphere within the interior.

In a closed-door purge method, the door remains in place as the purge gas is caused to flow into the substrate container interior, and an outlet of the container is opened to allow the gaseous interior atmosphere to be purged from the container interior and replaced with the purge gas. The door is opened after the purge gas has been added to the container interior and the previous atmosphere has been substantially purged.

1. A front opening wafer container comprising:
a container interior bounded by a bottom wall, a top wall, sidewalls, and a front opening,
a door to sealingly close the front opening,
a diffuser at the interior, adapted to dispense gas to the interior, the diffuser comprising:
an elongate body comprising: an upper end, a lower end, a front wall, a rear wall, sidewalls, a height between the upper end and the lower end, a width between the sidewalls, and a channel,
a diffuser inlet that allows flow of gas into the channel,
a diffuser outlet that comprises one or more openings in the front wall, a sidewall, or both,
a flow control structure within the channel that directs flow of gas along a length of the channel between the diffuser inlet and the diffuser outlet.

2. The container of claim 1, wherein the container interior comprises a front portion adjacent to the front opening and a back portion adjacent to a back sidewall, and the diffuser is oriented vertically and located in the front portion.

3. The container of claim 1, wherein:
the front wall of the diffuser comprises a width that includes a forward portion and a rearward portion, and the diffuser outlet is located at the forward portion.

4. The container of claim 3, wherein the forward wall of the diffuser extends along the height and comprises an upper portion, a lower portion, and a middle portion, and the diffuser outlet is located at the upper portion and the lower portion, but not at the middle portion.

5. The container of claim 1, wherein the diffuser inlet is located at a middle third of the height.

6. The container of claim 1, the diffuser comprising a rear wall comprising a base surface and a flow control device extending from the base surface into the channel.

7. The container of claim 6, wherein the flow control device is located at the middle third of the height.

8. The container of claim 6, wherein the flow control device comprises a wall that extends from the base surface toward an interior surface of the front wall.

9. The container of claim 1, wherein the diffuser outlet comprises a directed opening that directs a flow of gas through the opening in a non-perpendicular direction relative to a surface of the forward wall.

10. A method of using a container of claim 1, the method comprising:
placing one or more wafers in the container,
closing the door to sealingly close the front opening,
dispensing gas into the interior through the diffuser.

11. A method of claim 10, comprising opening the door and dispensing the gas through the diffuser while the door is open.

12. A method of claim 10, comprising dispensing the gas through the diffuser while the door is sealed and while a vent in the container is open.

13. The method of claim 10, wherein the container interior comprises a front portion adjacent to the front opening and a back portion adjacent to a back sidewall, and the diffuser is located in the front portion of the container, the method comprising:
dispensing the gas through the diffuser while the door is open, and
dispensing the gas in a direction of the front opening to cause flow of the gas through the front opening and reduce flow of exterior gas from a container exterior into the container interior.

14. A diffuser comprising:
an elongate body comprising: an upper end, a lower end, a front wall, a rear wall, sidewalls, a height between the upper end and the lower end, a width between the sidewalls, and a channel,
a diffuser inlet that allows flow of gas into the channel,
a diffuser outlet that comprises one or more openings in the front wall, the sidewalls, or both
non-porous channel surfaces comprising a non-porous rear wall surface and non-porous sidewall surfaces,
a flow control structure within the channel that directs flow of gas along a length of the channel between the diffuser inlet and the diffuser outlet.

15. The diffuser of claim 14, wherein:
the front wall comprises a width that includes a forward portion and a rearward portion, and the diffuser outlet is located at the forward portion and not at the rearward portion.

16. The diffuser of claim 14, wherein the forward wall of the diffuser extends along the height and comprises an upper portion, a lower portion, and a middle portion, and the diffuser outlet is located at the upper portion and the lower portion, but not at the middle portion.

17. The diffuser of claim 14, wherein the diffuser inlet is located at a middle third of the height.

18. The diffuser of claim 14, the diffuser comprising a rear wall comprising a base surface and a flow control device extending from the base surface into the channel.

19. The diffuser of claim 14, wherein the flow control device is located at a middle third of the height.

20. The diffuser of claim 14, wherein the flow control device is moveable relative to the channel.

21. The diffuser of claim 18, wherein the flow control device comprises a wall that extends from the base surface toward an interior surface of the front wall.

22. The diffuser of claim 14, wherein the diffuser outlet comprises a directed opening that directs a flow of gas through the opening in a non-perpendicular direction relative to a surface of the forward wall.
